(19) United States
(12) Patent Application Publication
(10) Pub. No.: US 2007/0155039 A1
(43) Pub. Date: Jul. 5, 2007

(54) Method for manufacturing CMOS image sensor

(75) Inventor: An Do Ki, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,803

(22) Filed: Dec. 27, 2006

(30) Foreign Application Priority Data
Dec. 29, 2005 (KR) 10-2005-0134172

(51) Int. Cl. H01L 21/00

(52) U.S. Cl. 438/57

(57) ABSTRACT

A method for manufacturing a CIS reduces or prevents dark current in a photodiode region. In the method, a plurality of gates are formed on a semiconductor substrate, and impurities are implanted in side portions of a predetermined gate to form a photodiode region. Subsequently, a spacer nitride layer is formed and then etched to form a first spacer pattern covering the photodiode region and a second spacer pattern on sidewalls of the rest of the gates. After that, impurities are implanted using the first and second spacer patterns as a mask to form source/drain regions in portions of the semiconductor substrate that are exposed at the side portions of the gate(s). Subsequently, a salicide is formed on the gate and in the exposed portion of the semiconductor substrate.

### BACKGROUND OF THE INVENTION

1. Field of the Invention

The present invention relates to a complementary metal oxide semiconductor image sensor (CMOS), and more particularly, to a method for manufacturing a CMOS image sensor, wherein a process has been improved in order to reduce or prevent a dark current of a photodiode region.

2. Description of the Related Art

Generally, an image sensor is a semiconductor device for converting an optical image into an electrical signal. The image sensor is roughly classified into a charge coupled device (CCD) and a CMOS image sensor (CIS).

The CCD not only has a complicated driving method and high -power consumption but also requires a plurality of mask processes. Also, the CCD has disadvantages that a signal processing circuit cannot be realized inside a CCD chip and thus it is difficult to manufacture the CCD in one chip. Accordingly, a CIS using a CMOS manufacturing technology is in the limelight recently.

A method for manufacturing a CIS according to a related art will be described with reference to the accompanying drawings.

FIGS. 1A to 1D are cross-sectional views explaining a method for manufacturing a CIS according to a related art.

Referring to FIG. 1A, a device isolation layer (STI) (not shown) is formed on a semiconductor substrate 10 formed of an epitaxial layer. By forming the STI, a device isolation region is separated from an active region.

Subsequently, p-type impurities are implanted in a portion of an active region belonging to a portion of the semiconductor substrate 10 that excludes the STI to form a p-well 12. The portion of the active region is defined at the rest portion of the semiconductor substrate 10 that excludes a portion in which a PD is to be formed. Here, the rest region in which the p-well 12 is not formed is defined as a p-sub substrate 11.

Subsequently, an oxide layer and a gate poly layer are sequentially deposited on the semiconductor substrate 10, and etched such that the oxide layer and the gate poly layer have the same width to form a gate pattern in which a gate oxide layer 15 and a gate poly layer 16 are stacked.

Subsequently, a first photoresist (not shown) is formed on the semiconductor substrate 10 to cover portions where a photodiode (PD) and an adjacent transport transistor are to be formed. After that, n-type impurity ions are implanted using the first photoresist layer as a mask to form an n-lightly doped drain (LDD) region 17.

Subsequently, a second photoresist layer (not shown) covering portions excluding the portion in which a PD is to be formed is formed. n-type impurity ions are implanted in the semiconductor substrate using the second photoresist layer as a mask to form a PD N-type (PDN) region 13.

After that, p-type impurity ions are implanted using a third photoresist (not shown) having a shape opening a partial surface of the PDN region 13 as a mask to form a PD P-type region 14 on a surface of the PDN region 13.

Referring to FIG. 1B, after the third photoresist layer is removed, a spacer nitride layer 18 is deposited on an entire surface of the semiconductor substrate 10 including the gate oxide layer 15 and a gate poly 16. The deposited spacer nitride layer 18 is selectively removed to form spacers 18a at lateral portions of the gate pattern 15 and 16, respectively.

Subsequently, impurity ions are implanted using the gate poly 16 and the spacers 18a as a mask to form source/drain regions 19 in the semiconductor substrate 10.

Referring to FIG. 1C, after an oxide layer 20 and a photoresist layer 21 are formed on a surface of the semiconductor substrate 10 including the gate pattern 15 and 16, and the spacer 18a, the oxide layer 20 and the photoresist layer 21 are etched to leave a shape covering the PD regions 13 and 14 from a central portion of the gate pattern 15 and 16.

Here, a portion 15a of the gate oxide layer 15 is also removed together with a removed portion of the photoresist layer 21 while the oxide layer 20 is etched.

Referring to FIG. 1D, after the photoresist layer 21 is removed, a salicide is formed on surfaces of an open portion of the gate poly 16 and an open portion of the semiconductor substrate 10.

In this case, a salicide is formed on the n-LDD region 17 and the open portion of the gate poly 16.

Since the photodiode region is a region for receiving light to generate electrons, it is preferable that a salicide layer reflecting light is absent. Therefore, the photodiode region should be non-salicide processed.

Accordingly, as illustrated, an oxide layer is deposited on an entire surface of the semiconductor substrate, and a portion of the oxide layer that corresponds to the PD is etched.

At this point, for stably forming the salicide, the salicide region is managed such that a remaining oxide layer has a thickness of about 40 Å or less (the remaining oxide layer is completely removed during an entire cleaning process of salicide) on a surface of the semiconductor substrate after the oxide layer is etched. Accordingly, plasma damage is directly applied to the surface of the semiconductor substrate 10, which makes it difficult to manage a threshold voltage Vth of a p-channel MOS (PMOS) transistor.

Due to the plasma damage, a surface lattice structure of silicon of the semiconductor substrate 100 is destroyed, boron having high thermal diffusivity diffuses into a channel region to reduce a threshold voltage Vth of the PMOS transistor. Fluctuation in the threshold voltage Vth becomes considerably serious depending on a plasma effect, resulting in a considerable problem in managing stability of a device.

### SUMMARY OF THE INVENTION

Accordingly, the present invention is directed to a method for manufacturing a CMOS image sensor that substantially obviates one or more problems due to limitations and disadvantages of the related art.

An object of the present invention is to provide a method for manufacturing a CMOS image sensor, wherein a process has been improved in order to prevent a dark current of a photodiode region.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for manufacturing a complementary meal oxide semiconductor image sensor, the method including: forming a plurality of gates separated from each other on a semiconductor substrate; implanting impurities in side portions of a predetermined gate of the gates to form a photodiode region; forming a spacer nitride layer on an entire surface of the semiconductor substrate including the gates; selectively removing the spacer nitride layer to form a first spacer pattern covering the photodiode region and a second spacer pattern on sidewalls of the rest of the gates; implanting impurities using the first and second spacer patterns as a mask to source/drain regions in portions of the semiconductor substrate that are exposed at the side portions of the gate; and forming a silicide in the gate and in the exposed portion of the semiconductor substrate.

The method further includes, prior to the forming of the plurality of gates, depositing a gate oxide layer.

The method further includes, after the selectively removing of the spacer nitride layer, removing an exposed portion of the gate oxide layer.

The method further includes, prior to the forming of the silicide, performing precleaning on exposed portions.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1A to 1D are cross-sectional views explaining a method for manufacturing a CIS according to a related art; and

FIG. 2A to 2D are cross-sectional views explaining a method for manufacturing a CIS according to the present invention.

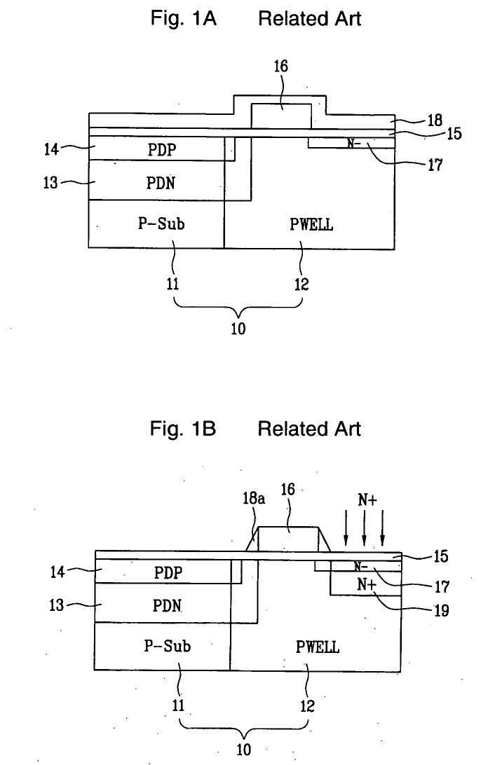

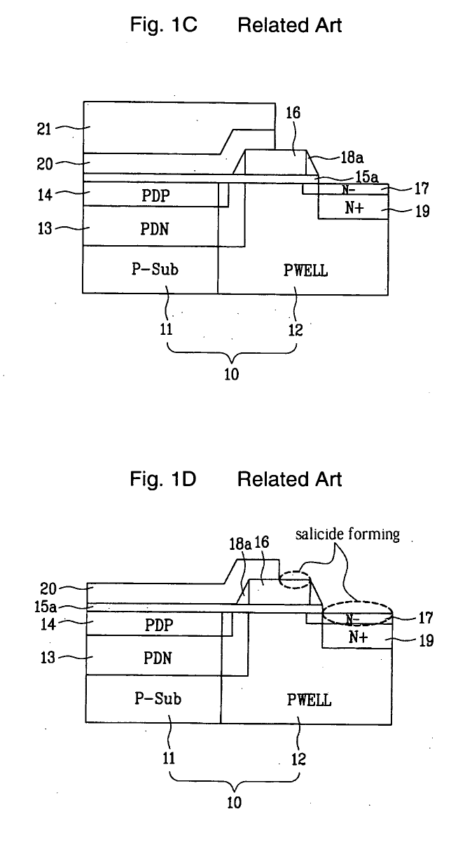

### DETAILED DESCRIPTION OF THE INVENTION

Reference will now be made in detail to the preferred embodiments of the present invention, examples of which are illustrated in the accompanying drawings.

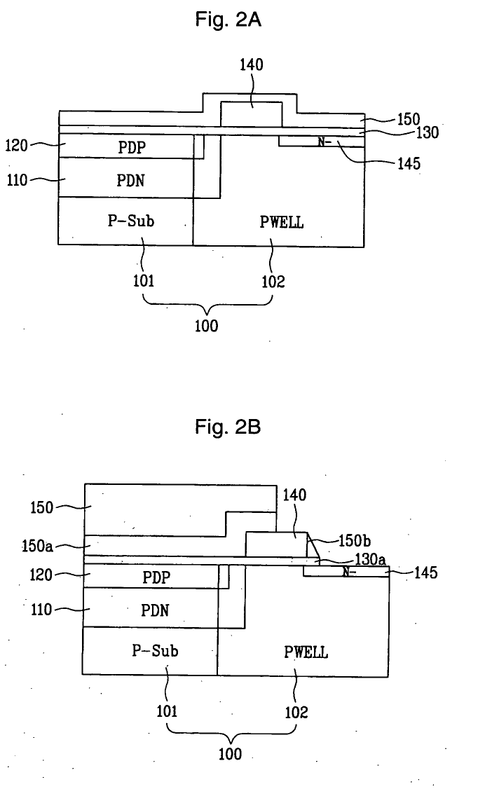

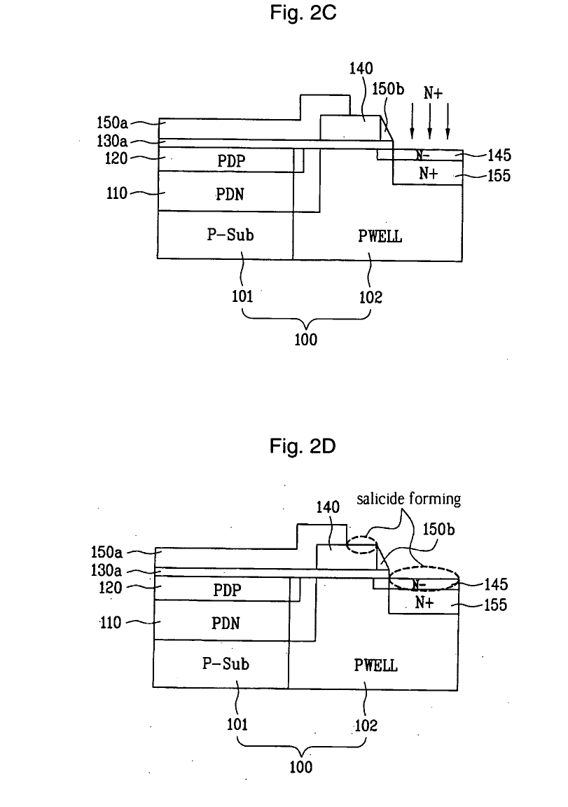

FIG. 2A to 2D are cross-sectional views explaining a method for manufacturing a CIS according to the present invention.

Referring to FIG. 2A, an STI (not shown) is formed on a semiconductor substrate 100 formed of an epitaxial layer. By forming the STI, a device isolation region is separated from an active region.

Subsequently, p-type impurities are implanted in a portion of an active region belonging to a portion of the semiconductor substrate 100 that excludes the STI to form a p-well 102. The portion of the active region is defined at the rest portion of the semiconductor substrate 100 that excludes a portion in which a PD is to be formed. Here, the rest region in which the p-well 102 is not formed is defined as a p-sub substrate 101.

Sugbsequently, an oxide layer and a gate layer are sequentially deposited on the semiconductor substrate 100, and etched such that the oxide layer and the gate layer have the same width to form a gate pattern in which a gate oxide layer 130 and a gate layer 140 are stacked.

Subsequently, a first photoresist (not shown) is formed on the semiconductor substrate 100 to cover portions where a photodiode (PD) and an adjacent transport transistor are to be formed. After that, n-type impurity ions are implanted using the first photoresist layer as a mask to form an n-lightly doped drain (LDD) region.

Subsequently, a second photoresist layer (not shown) covering portions excluding the portion in which a PD is to be formed is formed. n-type impurity ions are implanted in the semiconductor substrate using the second photoresist layer as a mask to form a PD N-type (PDN) region 110.

After that, p-type impurity ions are implanted using a third photoresist (not shown) having a shape opening a partial surface of the PDN region 110 as a mask to form a PD P-type region 120 on a surface of the PDN region 110.

Subsequently, after the third photoresist layer is removed, a spacer nitride layer 150 is deposited on an entire surface of the semiconductor substrate 100 including the gate oxide layer 130 and the gate poly 140. Here, the spacer nitride layer is formed of SiN.

Referring to FIG. 2B, a photoresist layer is coated on an entire surface of the spacer nitride layer 150, and exposed and developed to form a photoresist pattern 160. Here, the photoresist pattern has a shape covering the PD region and a portion of the gate poly.

Subsequently, the spacer nitride layer 150 is etched using the photoresist pattern 160 as a mask to form a spacer nitride layer pattern 150a. A spacer nitride layer pattern left when the spacer nitride layer 150 is etched includes a first spacer nitride layer pattern 150a and a second spacer nitride layer pattern 150b. Here, the first spacer nitride layer pattern 150a has a shape covering the PD region 110, and the second spacer nitride layer pattern 150b has a shape left on a sidewall of the open gate poly 140.

Referring to FIG. 2C, impurity ions are implanted using the first and second spacer nitride layer patterns 150a and 150b, and the gate poly 140 as a mask to form source/drain regions 155.

Referring to FIG. 2D, a salicide is formed on open portions of the gate poly 140 and the semiconductor substrate 100 with the gate poly 140, and the first and second spacer nitride layer patterns 150a and 150b left. In this case, the salicide is formed on the n-LDD region 145 and the open portion of the gate poly 140.

As described above, the method for manufacturing a CIS according to the present invention leaves PD regions 110 and 120 during a process of etching the spacer nitride layer, forms source/drain regions, and performs a salicide process. Accordingly, a damage that may be generated on a surface of the PD region can be prevented when the spacer nitride layer is etched.

In the CIS according to the present invention, in the case where a spacer nitride layer is left after the spacer nitride layer is formed on the PD region, the spacer nitride layer is left during an impurity implantation process in order to prevent a dark current caused by a dangling bond on a surface of a PD from being generated when the PD region is exposed.

An ion implantation process condition needs to be slightly modified depending on a product in manufacturing a CIS of the present invention. An ion implantation process may not be performed on a PD region after a spacer nitride layer process depending on a product. In the case where the ion implantation process is performed, the ion implantation process is performed before the spacer nitride layer is manufactured, or the ion implantation process is performed by controlling an ion implantation project region.

In a method for manufacturing a CIS according to the present invention, fluctuation in a threshold voltage of a PMOS that is caused by plasma damage can be removed during the non-salicide process. According to the related art, the non-salicide process has been performed on the condition that an oxide layer residue is formed in a thickness of about 40 Å on a salicide region and the oxide layer residue is removed by a thickness of about 50 Å using a diluted HF (DHF) solution during a precleaning process of salicide. On the other hand, according to the CIS of the present invention, since an oxide layer has a residual layer having a thickness of 100 Å after a spacer nitride layer is etched, the oxide layer is removed by 125 Å using a DHF solution.

The CIS of the present invention has the following effects.

First, since a spacer nitride layer on a PD region is not removed, a surface damage exerted during a reactive ion etching (RIE) process of s spacer nitride layer can be removed, leakage electron generation is reduced and thus malfunction caused by a dark current can be prevented.

Second, since a non-salicide process can be omitted, a defect rate can be reduced through process simplification.

Third, a fluctuation problem of a threshold voltage of a PMOS that is caused by a plasma damage can be removed while RIE of a non-salicide is performed.

Fourth, a PD region can be protected more surely, it is possible to prevent an increase in a dark current caused by a leakage characteristic of a PD, and yield reduction.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for manufacturing a complementary metal oxide semiconductor image sensor, the method comprising:
forming a plurality of gates separated from each other on a semiconductor substrate;
implanting impurities in side portions of a predetermined gate to form a photodiode region;
forming a nitride layer on an entire surface of the semiconductor substrate including the gates;
selectively removing portions of the spacer nitride layer to form a first spacer pattern covering the photodiode region and a second spacer pattern on sidewalls of remaining gates;
implanting impurities using the first and second spacer patterns as a mask to form source/drain regions in portions of the semiconductor substrate that are exposed at the side portions of the gate; and
forming a salicide on the exposed portion of the gate and the exposed portion of the semiconductor substrate.

2. The method according to claim 1, further comprising, prior to forming the plurality of gates, forming a gate oxide layer.

3. The method according to claim 2, further comprising, after selectively removing the spacer nitride layer, removing an exposed portion of the gate oxide layer.

4. The method according to claim 2, further comprising, prior to forming the salicide, precleaning exposed portions.

5. A method for manufacturing a complementary metal oxide semiconductor (CMOS) image sensor, the method comprising:
implanting impurities in a portion of the semiconductor adjacent to a gate to form a photodiode region and -in a portion of the gate;
forming a nitride pattern covering the photodiode region and a nitride spacer on an exposed sidewall of the gate;
implanting impurities using the gate, the nitride pattern and the nitride spacer as a mask to form a source/drain region in an exposed portion of the semiconductor adjacent to the gate; and
forming a salicide on the exposed portion of the gate and the exposed portion of the semiconductor.

6. The method according to claim 5, further comprising forming a plurality of gates separated from each other on the semiconductor.

7. The method according to claim 5, wherein forming the nitride pattern and the nitride spacer comprises selectively forming a nitride layer on an entire surface of the semiconductor, including the gate, and removing portions of the nitride layer to form the nitride pattern and the nitride spacer.

8. The method according to claim 7, wherein removing portions of the nitride layer comprises patterning a photoresist on the nitride layer, and anisotropically etching the exposed nitride layer to form the nitride spacer.

9. The method according to claim 8, wherein the nitride pattern is formed by removing the patterned photoresist.

10. The method according to claim 6, further comprising, prior to forming the plurality of gates, forming a gate oxide layer.

11. The method according to claim 10, further comprising, after forming the nitride spacer, removing an exposed portion of the gate oxide layer.

12. The method according to claim 5, further comprising, prior to forming the salicide, precleaning exposed portions of the semiconductor.

13. The method according to claim 5, further comprising forming a dielectric layer over the semiconductor, the photodiode and the gate.

14. The method according to claim 13, further comprising forming a color filter over the dielectric layer.

15. The method according to claim 14, wherein the color filter comprises one of a red, green or blue color filter or one of a yellow, cyan or magenta color filter.

16. The method according to claim 14, further comprising forming a planarization layer over the color filter.

17. The method according to claim 16, further comprising forming a microlens over the planarization layer.

18. The method according to claim 17, wherein the microlens has a convex shape, configured to direct and/or focus incident light onto the photodiode.

19. The method according to claim 17, wherein the dielectric layer and the planarization layer has a transmittance and a thickness configured to focus light from the microlens onto the photodiode.

20. The method according to claim 5, wherein the gate comprises polysilicon.
